(19) United States
(12) Patent Application Publication
(10) Pub. No.: US 2026/0025120 A1
(43) Pub. Date: Jan. 22, 2026

(54) Method Of Manufacturing Oscillator

(71) Applicant: SEIKO EPSON CORPORATION, Tokyo (JP)

(72) Inventor: Manabu KONDO, Matsumoto (JP)

(21) Appl. No.: 19/274,957

(22) Filed: Jul. 21, 2025

(30) Foreign Application Priority Data
Jul. 22, 2024 (JP) 2024-116777

(51) Int. Cl. H03H 9/08; H03H 3/013; H03H 9/125

(52) U.S. Cl. CPC H03H 9/08; H03H 3/013; H03H 9/125

(57) ABSTRACT

A method of manufacturing an oscillator is a method of manufacturing the oscillator including a container in which a resonator is accommodated and a base substrate, and the method includes forming a first projecting portion on the container, forming a second projecting portion on the base substrate, and bonding the first projecting portion and the second projecting portion with a bonding material interposed therebetween to mount the container on the base substrate.

The present application is based on, and claims priority from JP Application Serial Number 2024-116777, filed Jul. 22, 2024, the disclosure of which is hereby incorporated by reference herein in its entirety.

### BACKGROUND

### 1. Technical Field

The present disclosure relates to a method of manufacturing an oscillator.

### 2. Related Art

For example, JP-A-2022-36479 discloses an oscillator in which a second container for accommodating a resonator is mounted, via three or more projecting portions, on a base substrate constituting a first container for accommodating the second container, so that the oscillator has improved heat insulation properties between the resonator and the outside and excellent frequency stability. The projecting portions are formed by applying an insulating adhesive to the base substrate with a dispenser, and heating and curing the adhesive.

However, in the oscillator described in JP-A-2022-36479, although the gap between the second container and the base substrate can be further increased and the heat insulation properties can be further improved by stacking a plurality of projecting portions on the base substrate and mounting the second container thereon, in order to stack the plurality of projecting portions, it is necessary to stack a plurality of layers of an adhesive, and there is a problem in which the position and the amount of the adhesive to be applied for the upper layer are strictly restricted.

### SUMMARY

A method of manufacturing an oscillator is a method of manufacturing an oscillator including a container in which a resonator is accommodated and a base substrate, and the method includes forming a first projecting portion on the container, forming a second projecting portion on the base substrate, and bonding the first projecting portion and the second projecting portion with a bonding material interposed therebetween to mount the container on the base substrate.

### BRIEF DESCRIPTION OF THE DRAWINGS

FIG. 1 is a plan view illustrating a schematic structure of an oscillator manufactured by a method of manufacturing an oscillator according to a first embodiment.

FIG. 2 is a sectional view taken along line II-II in FIG. 1.

FIG. 3 is a sectional view taken along line III-III in FIG. 1.

FIG. 4 is a flowchart illustrating the method of manufacturing an oscillator according to the first embodiment.

FIG. 5 is a view for explaining the method of manufacturing an oscillator.

FIG. 6 is a view for explaining the method of manufacturing an oscillator.

FIG. 7 is a view for explaining the method of manufacturing an oscillator.

FIG. 8 is a view for explaining the method of manufacturing an oscillator.

FIG. 9 is a view for explaining the method of manufacturing an oscillator.

FIG. 10 is a plan view illustrating a schematic structure of an oscillator manufactured by a method of manufacturing an oscillator according to a second embodiment.

FIG. 11 is a sectional view taken along line XI-XI in FIG. 10.

FIG. 12 is a plan view illustrating a schematic structure of an oscillator manufactured by a method of manufacturing an oscillator according to a third embodiment.

FIG. 13 is a sectional view taken along line XIII-XIII in FIG. 12.

FIG. 14 is a plan view illustrating a schematic structure of an oscillator manufactured by a method of manufacturing an oscillator according to a fourth embodiment.

FIG. 15 is a sectional view taken along line XV-XV in FIG. 14.

FIG. 16 is a plan view illustrating a schematic structure of an oscillator according to a first modification.

FIG. 17 is a sectional view taken along line XVII-XVII in FIG. 16.

FIG. 18 is a plan view illustrating a schematic structure of an oscillator according to a second modification.

FIG. 19 is a sectional view taken along line XIX-XIX in FIG. 18.

### DESCRIPTION OF EMBODIMENTS

### 1. First Embodiment

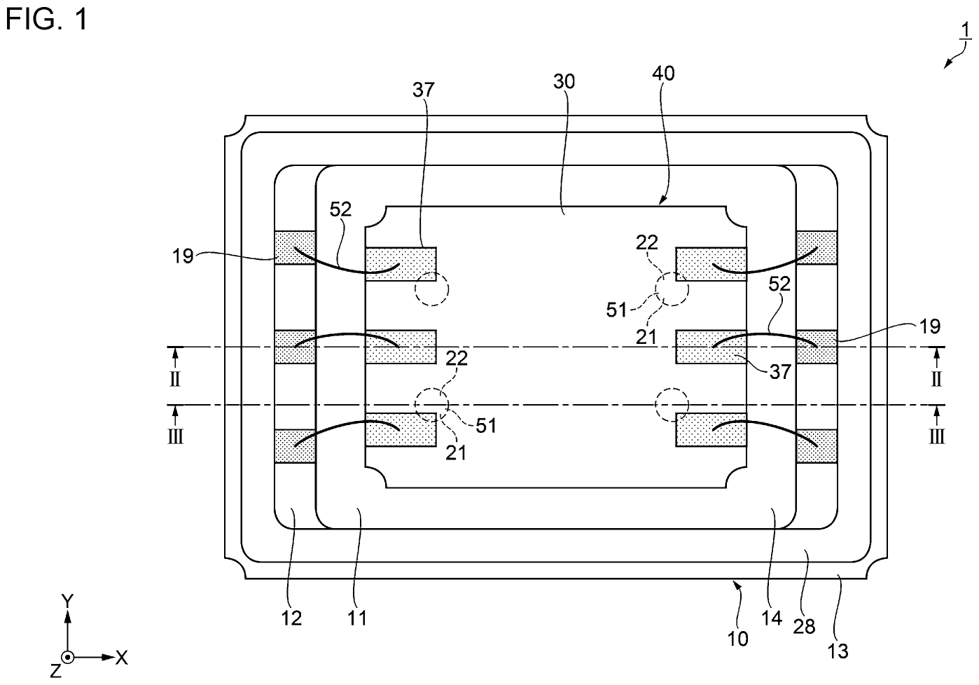

First, an oscillator 1 manufactured by a method of manufacturing an oscillator according to a first embodiment will be described with reference to FIGS. 1, 2, and 3 by taking a temperature compensated oscillator having a double seal structure as an example.

In FIG. 1, for convenience of description of the internal configuration of the oscillator 1, a state in which a lid 27 is removed is illustrated. In FIGS. 1, 2, and 3, wiring for electrically connecting internal terminals 19 provided in an accommodation container 5 to external terminals 20, and terminals and wiring provided in a container 30 are not illustrated.

In addition, for convenience of description, an X-axis, a Y-axis, and a Z-axis are illustrated as three axes orthogonal to each other in the following plan views and sectional views. Moreover, a direction along the X-axis is defined as an “X direction”, a direction along the Y-axis is defined as a “Y direction”, and a direction along the Z-axis is defined as a “Z direction”. In addition, a leading end side of an arrow in each axial direction is also referred to as a “plus side”, and a base end side is also referred to as a “minus side”.

As illustrated in FIGS. 1, 2, and 3, the oscillator 1 according to the present embodiment includes a temperature compensated oscillator 40, in which an integrated circuit 41 and a resonator 43 are accommodated in the container 30, and the accommodation container 5 that accommodates the temperature compensated oscillator 40.

The temperature compensated oscillator 40 includes the integrated circuit 41, the resonator 43, and the container 30 that accommodates the resonator 43 and the integrated circuit 41.

The container 30 includes a base 31 made of ceramic or the like, and a lid 32 made of metal, ceramic, glass, or the like, and the base 31 and the lid 32 are bonded to each other with a bonding member 36 such as a seal ring or low-melting-point glass interposed therebetween.

A plurality of first projecting portions 21 formed of an insulating adhesive is provided on the lid 32 of the container 30. The first projecting portions 21 can be formed by applying an insulating adhesive onto the lid 32 of the container 30 with a dispenser or the like and then heating and curing the insulating adhesive. By making the discharge amount from the dispenser constant, the diameters and the heights of the first projecting portions 21 can be made uniform.

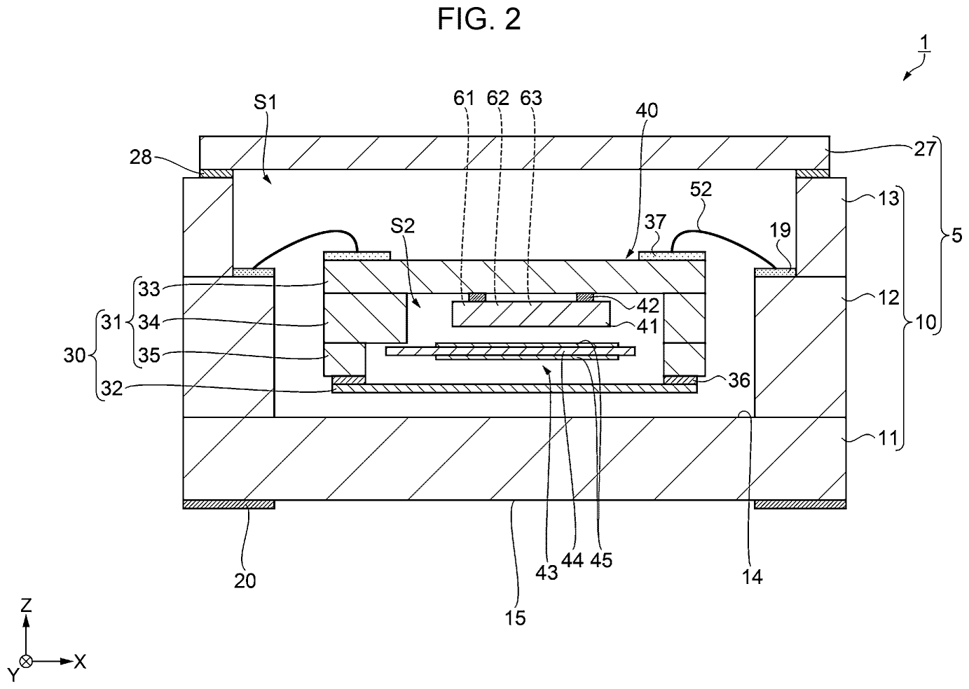

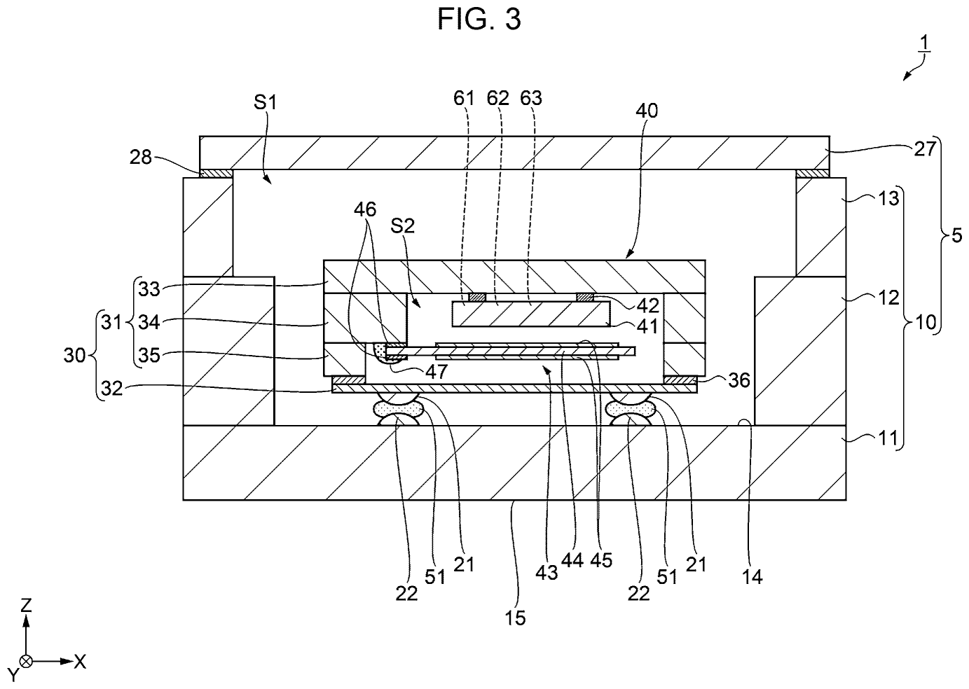

As illustrated in FIGS. 2 and 3, the base 31 is formed by stacking a first substrate 33 having a flat plate shape, a second substrate 34 having an annular shape whose central portion is removed, and a third substrate 35 having an annular opening portion larger than that of the second substrate 34. In addition, a plurality of terminals 37 is provided on a surface of the first substrate 33 opposite to the second substrate 34. An accommodation space S2 for accommodating the resonator 43 and the integrated circuit 41 is formed inside the base 31 by the annular second substrate 34 and third substrate 35. The accommodation space S2 is an airtight space and is filled with an inert gas such as nitrogen, helium, or argon. The atmosphere of the accommodation space S2 is not particularly limited, and may be, for example, a reduced pressure state or a pressurized state.

As illustrated in FIG. 2, the integrated circuit 41 is fixed to a surface of the first substrate 33 on the accommodation space S2 side with conductive bonding members 42 such as metal bumps or solder interposed therebetween. In addition, as illustrated in FIG. 3, the resonator 43 is fixed to a surface of a portion of the second substrate 34 which does not overlap with the third substrate 35 with a conductive bonding member 47 such as a conductive adhesive interposed therebetween.

The integrated circuit 41 is electrically connected to the terminals 37 via wiring (not illustrated), through electrodes (not illustrated), or the like provided on the surface of the first substrate 33 on the accommodation space S2 side. In addition, the resonator 43 is electrically connected to the integrated circuit 41 via a terminal (not illustrated), a through electrode (not illustrated), or the like provided on the surface of a portion of the second substrate 34 which does not overlap with the third substrate 35.

The integrated circuit 41 is accommodated in the accommodation space S2 of the container 30 and includes an oscillation circuit 61 for oscillating the resonator 43, a temperature compensation circuit 62 for temperature-compensating the deviation of the oscillation frequency of the resonator 43 from a desired frequency in a predetermined temperature range, and a temperature sensor 63 for detecting the temperature in the accommodation space S2.

The resonator 43 includes a plate-like substrate 44, excitation electrodes 45 provided on two surfaces of the substrate 44, which are the front and back surfaces of the substrate 44, and pad electrodes 46. The resonator 43 has a cantilever structure in which one end portion in the X direction is fixed to the container 30 by the bonding member 47. The excitation electrodes 45 and the pad electrodes 46 are electrically connected to each other by lead electrodes (not illustrated) provided on the two surfaces. Therefore, the excitation electrodes 45 are electrically connected to the integrated circuit 41 via the pad electrodes 46 and the conductive bonding member 47. The resonator 43 oscillates at a frequency corresponding to the mass of the substrate 44 including the excitation electrodes 45. As the resonator 43, for example, a quartz crystal resonator, a surface acoustic wave (SAW) resonator, other piezoelectric resonators, a micro electro mechanical systems (MEMS) resonator, or the like can be used. As the material of the substrate 44, a piezoelectric material, including a piezoelectric single crystal such as quartz crystal, lithium tantalate, or lithium niobate, and piezoelectric ceramics such as lead zirconate titanate, or a silicon semiconductor material and the like can be used.

The accommodation container 5 includes a base substrate 10 made of ceramic or the like and the lid 27 made of metal, ceramic, glass, or the like, and the base substrate 10 and the lid 27 are bonded to each other with a bonding member 28 such as a seal ring or low-melting-point glass interposed therebetween.

As illustrated in FIGS. 2 and 3, the base substrate 10 is formed by stacking a first substrate 11 having a flat plate shape, a second substrate 12 having an annular shape whose central portion is removed, and a third substrate 13 having an annular opening portion larger than that of the second substrate 12. As illustrated in FIG. 1, a plurality of the internal terminals 19 is provided on a surface of a portion of the second substrate 12 which does not overlap with the third substrate 13. In addition, a plurality of the external terminals 20 is provided on a second surface 15 which is a surface of the first substrate 11 opposite to the second substrate 12. The internal terminals 19 and the external terminals 20 are electrically connected to each other via through electrodes or the like (not illustrated). An accommodation space S1 for accommodating the temperature compensated oscillator 40 is formed inside the base substrate 10 by the annular second substrate 12 and third substrate 13. The accommodation space S1 is an airtight space and is filled with an inert gas such as nitrogen, helium, or argon. The atmosphere of the accommodation space S1 is not particularly limited, and may be, for example, a reduced pressure state or a pressurized state.

The first substrate 11 extends in the X direction and the Y direction and has a thickness in the Z direction. A first surface 14 of the first substrate 11 facing the container 30 is provided with a plurality of second projecting portions 22 formed of an insulating adhesive at positions overlapping with the first projecting portions 21 provided on the lid 32 of the container 30 in a plan view in the Z direction.

The second projecting portions 22 can be formed by applying an insulating adhesive onto the first surface 14 of the first substrate 11 with a dispenser or the like and then heating and curing the insulating adhesive. By making the discharge amount from the dispenser constant, the diameters and the heights of the second projecting portions 22 can be made uniform.

The container 30 is mounted on the base substrate 10 by bonding each first projecting portion 21 formed on the container 30 and each second projecting portion 22 formed on the base substrate 10 with a bonding material 51 interposed therebetween.

In the container 30 mounted on the base substrate 10, the terminals 37 provided on the first substrate 33 and the internal terminals 19 provided on the base substrate 10 are electrically connected to each other via bonding wires 52. Therefore, since the terminals 37 provided on the first substrate 33 and the external terminals 20 provided on the base substrate 10 are electrically connected to each other via the bonding wires 52, the internal terminals 19, through electrodes (not illustrated), and the like, it is possible to output a desired frequency temperature-compensated by the temperature compensated oscillator 40 from the external terminals 20.

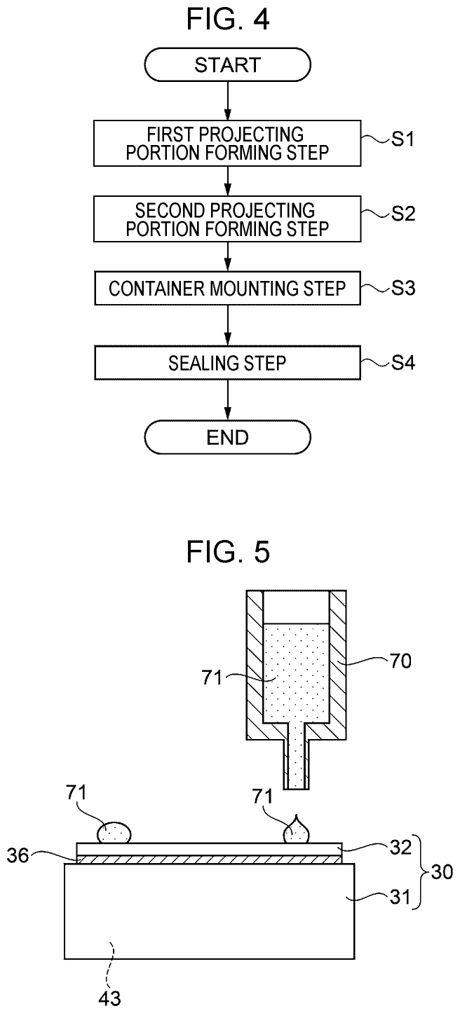

Next, a method of manufacturing the oscillator 1 according to the first embodiment will be described with reference to FIG. 4.

As illustrated in FIG. 4, the method of manufacturing the oscillator 1 includes a first projecting portion forming step S1, a second projecting portion forming step S2, a container mounting step S3, and a sealing step S4. The order of the first projecting portion forming step S1 and the second projecting portion forming step S2 may be reversed.

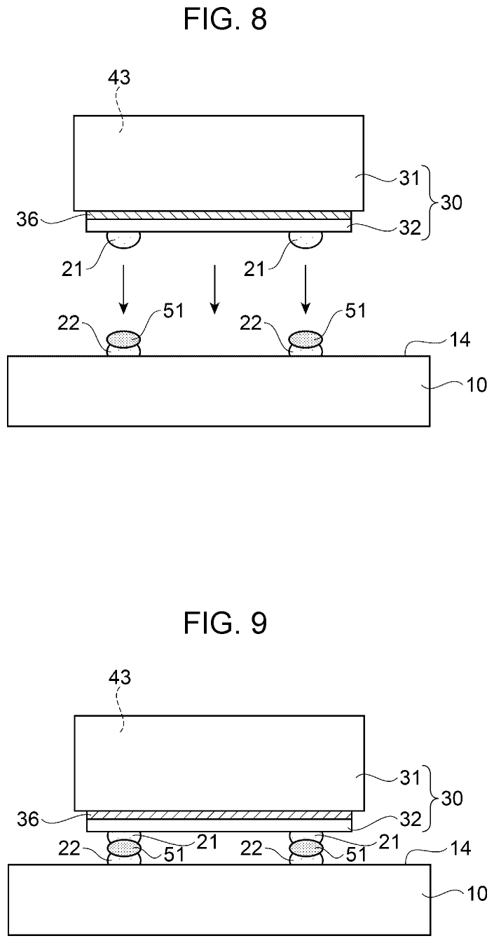

First, as the first projecting portion forming step S1, as illustrated in FIG. 5, an insulating adhesive 71 is applied onto the lid 32 of the container 30 using a dispenser 70 or the like. Thereafter, by heating and curing the insulating adhesive 71, as illustrated in FIG. 8, the hemispherical first projecting portions 21 are formed on the lid 32 of the container 30 in which the resonator 43 is accommodated. As a constituent material of the insulating adhesive 71, an epoxy resin, a polyimide resin, a silicon resin, or the like is used.

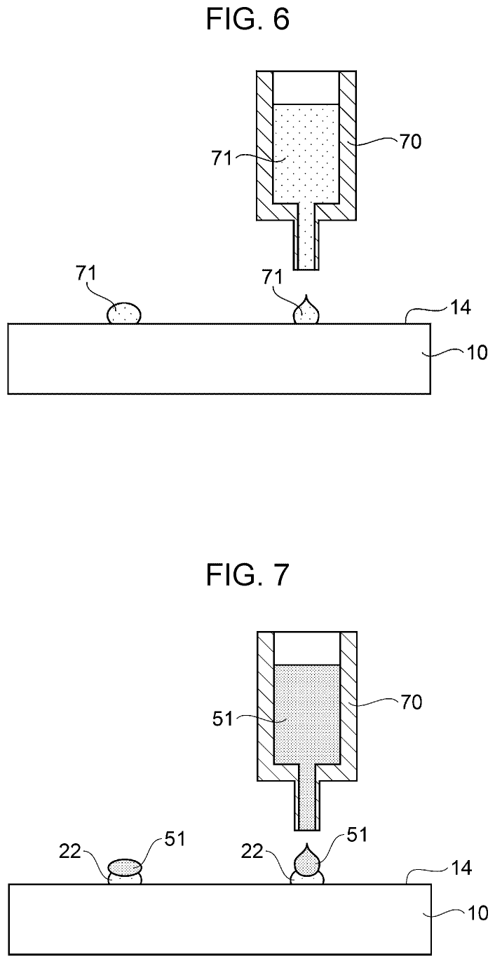

Next, as the second projecting portion forming step S2, as illustrated in FIG. 6, the insulating adhesive 71 is applied onto the first surface 14 of the base substrate 10 using the dispenser 70 or the like. Thereafter, by heating and curing the insulating adhesive 71, as illustrated in FIG. 7, the hemispherical second projecting portions 22 are formed on the base substrate 10.

Next, as the container mounting step S3, as illustrated in FIG. 7, the bonding material 51 is applied onto each of the second projecting portions 22 formed on the base substrate 10 using the dispenser 70 or the like. Thereafter, as illustrated in FIG. 8, after the container 30 is turned upside down, the container 30 is disposed such that each first projecting portion 21 formed on the container 30 overlaps with the bonding material 51 on each second projecting portion 22, and heating is performed in a state in which the first projecting portion 21 is pressed against the bonding material 51. The bonding material 51 is cured by heating, and the first projecting portion 21 and the second projecting portion 22 are bonded. Therefore, as illustrated in FIG. 9, the container 30 is mounted on the base substrate 10. As a constituent material of the bonding material 51, an epoxy resin, a polyimide resin, a silicon resin, or the like is used.

Next, as the sealing step S4, the terminals 37 provided in the container 30 mounted on the base substrate 10 and the internal terminals 19 provided on the base substrate 10 are electrically connected to each other via the bonding wires 52, and then the base substrate 10 and the lid 27 are bonded to each other with the bonding member 28 such as a seal ring or low-melting-point glass interposed therebetween, whereby the oscillator 1 accommodating the temperature compensated oscillator 40 is completed.

In the method of manufacturing the oscillator 1 of the present embodiment, after the first projecting portion 21 is formed on the container 30 accommodating the resonator 43 and the second projecting portion 22 is formed on the base substrate 10, the container 30 accommodating the resonator 43 is mounted on the base substrate 10 by bonding the first projecting portion 21 and the second projecting portion 22 to each other with the bonding material 51 interposed therebetween. That is, in order to further increase the gap between the container 30 and the base substrate 10, the first projecting portion 21 and the second projecting portion 22 are individually formed and are bonded to each other in an overlapping manner. Therefore, it is possible to increase the degree of freedom of the position and the amount of the insulating adhesive 71 to be applied, compared to a case where a plurality of projecting portions are stacked on the base substrate 10. Therefore, it is possible to easily manufacture the oscillator 1 having improved heat insulation properties and excellent frequency stability.

### 2. Second Embodiment

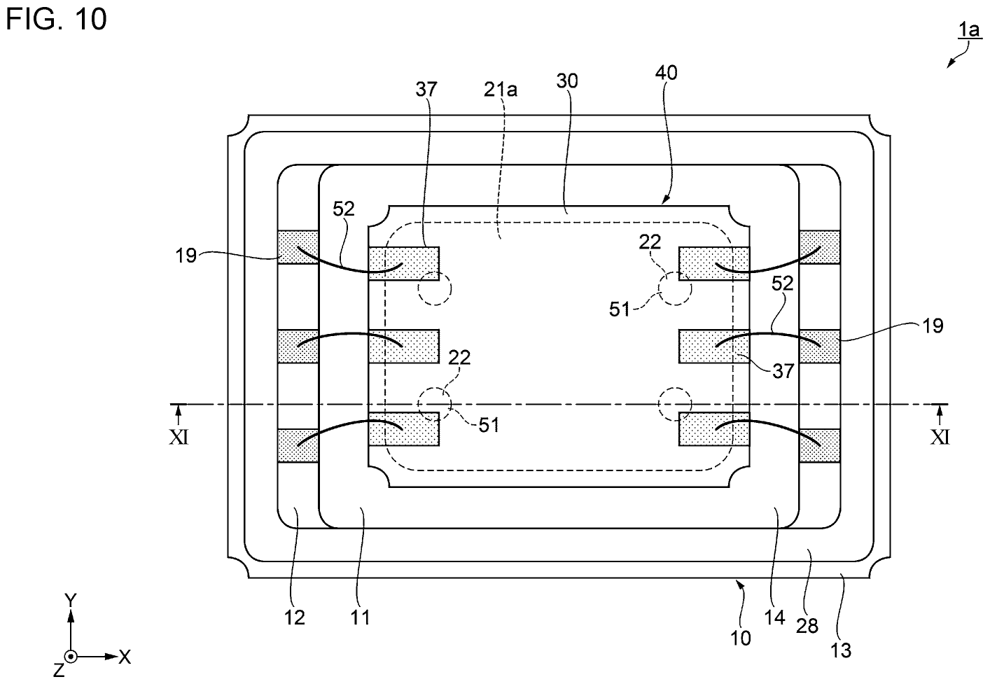

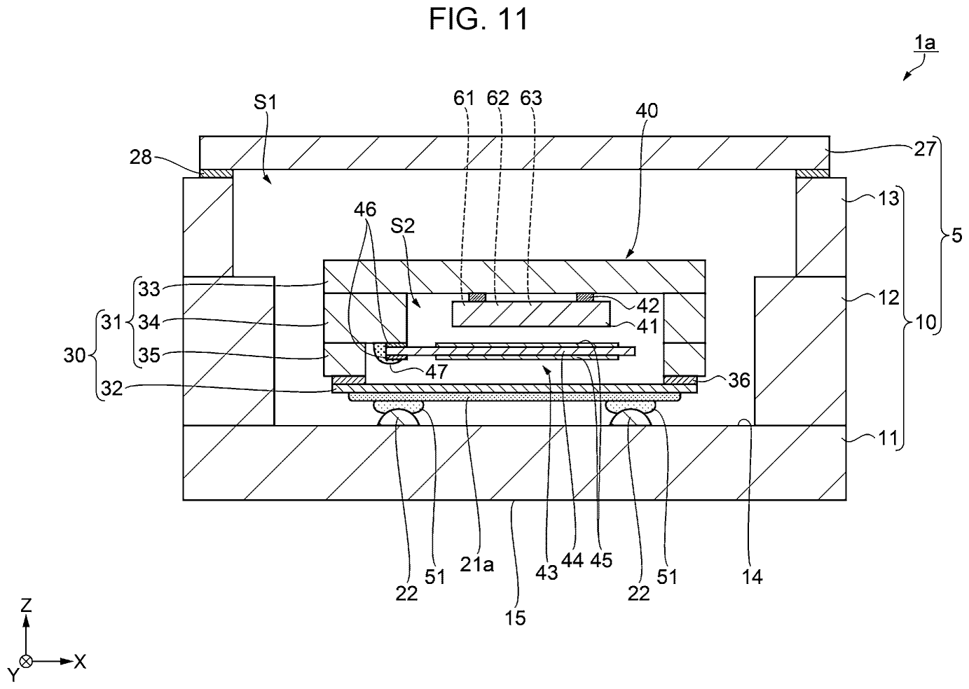

Next, an oscillator 1a manufactured by a method of manufacturing an oscillator according to a second embodiment will be described with reference to FIGS. 10 and 11. For convenience of description, FIG. 10 illustrates a state in which the lid 27 is removed.

The oscillator 1a of the present embodiment is the same as the oscillator 1 of the first embodiment except that the area of a first projecting portion 21a provided on the container 30 is different compared to the oscillator 1 of the first embodiment. Differences from the first embodiment described above will be mainly described, and the description of the same matters will be omitted.

In the oscillator 1a, as illustrated in FIGS. 10 and 11, the container 30 is mounted on the base substrate 10 by bonding the first projecting portion 21a formed on the container 30 accommodating the resonator 43 and each of the second projecting portions 22 formed on the base substrate 10 with the bonding material 51 interposed therebetween.

The projection of the first projecting portion 21a has a larger area in plan view than any of a plurality of projections of the second projecting portions 22. In addition, the projection of the first projecting portion 21a is bonded to each of the plurality of projections of the second projecting portions 22. That is, the area of one first projecting portion 21a is larger than the area including the plurality of second projecting portions 22, and the one first projecting portion 21a and the plurality of second projecting portions 22 are bonded to each other.

In a method of manufacturing the oscillator 1a of the present embodiment, in the first projecting portion forming step S1, the insulating adhesive 71 is applied to substantially the entire surface of the lid 32 of the container 30 using the dispenser 70 or the like, and one first projecting portion 21a is formed. Therefore, the area of the projection of the first projecting portion 21a is larger than the area including the plurality of projections of the second projecting portions 22, and the first projecting portion 21a and the second projecting portions 22 are easily aligned when the container 30 is mounted on the base substrate 10. Therefore, the container 30 is easily mounted on the base substrate 10 in the container mounting step S3.

### 3. Third Embodiment

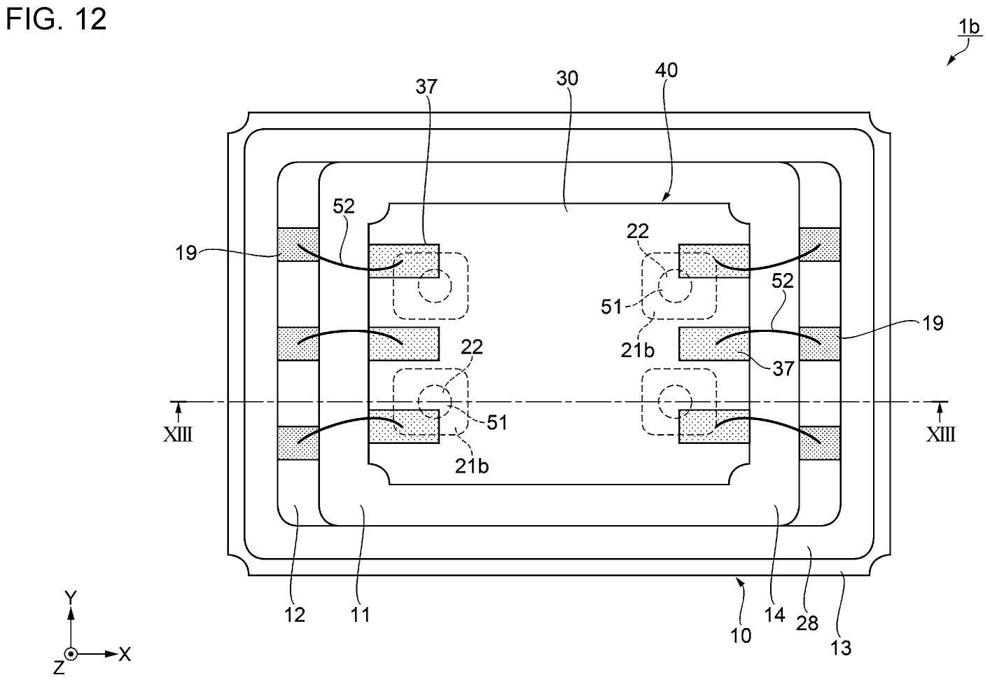

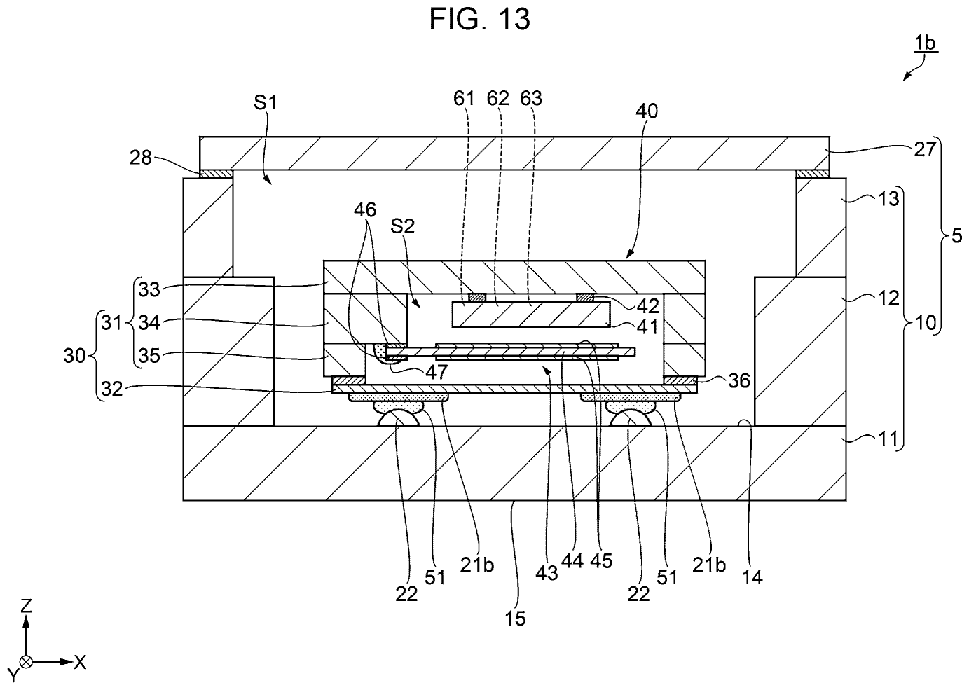

Next, an oscillator 1b manufactured by a method of manufacturing an oscillator according to a third embodiment will be described with reference to FIGS. 12 and 13. For convenience of description, FIG. 12 illustrates a state in which the lid 27 is removed.

The oscillator 1b of the present embodiment is the same as the oscillator 1 of the first embodiment except that the areas of first projecting portions 21b provided on the container 30 are different compared to the oscillator 1 of the first embodiment. Differences from the first embodiment described above will be mainly described, and the description of the same matters will be omitted.

In the oscillator 1b, as illustrated in FIGS. 12 and 13, the container 30 is mounted on the base substrate 10 by bonding each of the first projecting portions 21b formed on the container 30 accommodating the resonator 43 and each of the second projecting portions 22 formed on the base substrate 10 with the bonding material 51 interposed therebetween.

The projections of the first projecting portions 21b each have a larger area in plan view than any of the plurality of projections of the second projecting portions 22. In addition, the projections of the first projecting portions 21b are each bonded to any one of the plurality of projections of the second projecting portions 22. That is, the areas of the first projecting portions 21b are larger than the areas of the second projecting portions 22 facing the first projecting portions 21b, and the first projecting portions 21b and the second projecting portions 22 facing the first projecting portions 21b are bonded to each other.

In a method of manufacturing the oscillator 1b of the present embodiment, when the insulating adhesive 71 is applied onto the lid 32 of the container 30 using the dispenser 70 or the like in the first projecting portion forming step S1, the amount of the insulating adhesive 71 to be applied is larger than the amount applied in the second projecting portion forming step S2, so that the first projecting portions 21b are formed. Therefore, the areas of the projections of the first projecting portions 21b are larger than the areas of the projections of the second projecting portions 22 facing the first projecting portions 21b, and the first projecting portions 21b and the second projecting portions 22 are easily aligned when the container 30 is mounted on the base substrate 10. Therefore, the container 30 is easily mounted on the base substrate 10 in the container mounting step S3.

### 4. Fourth Embodiment

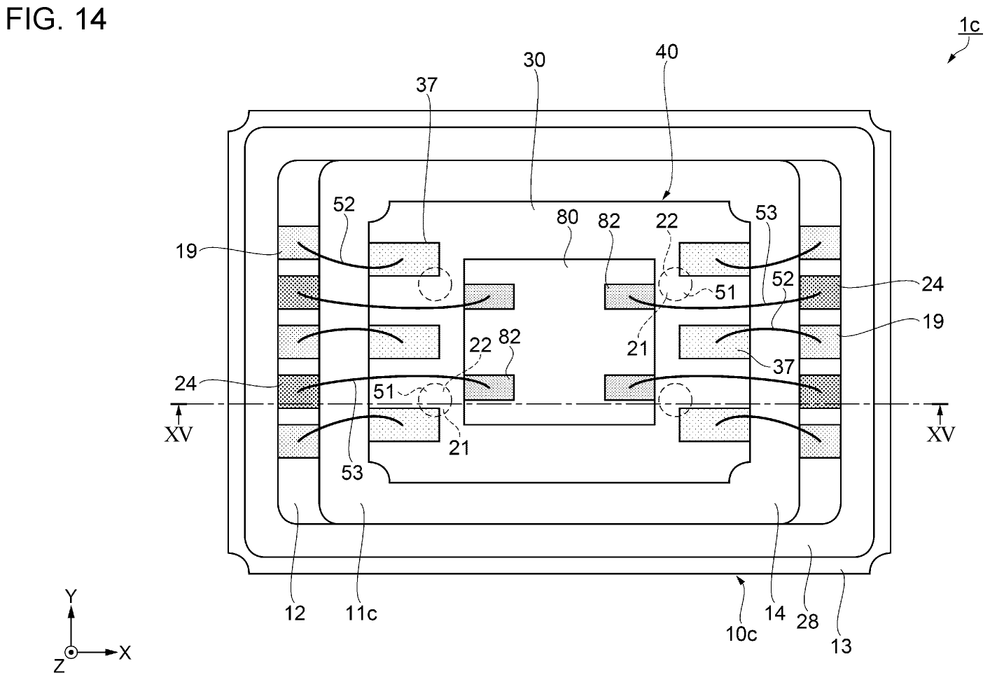

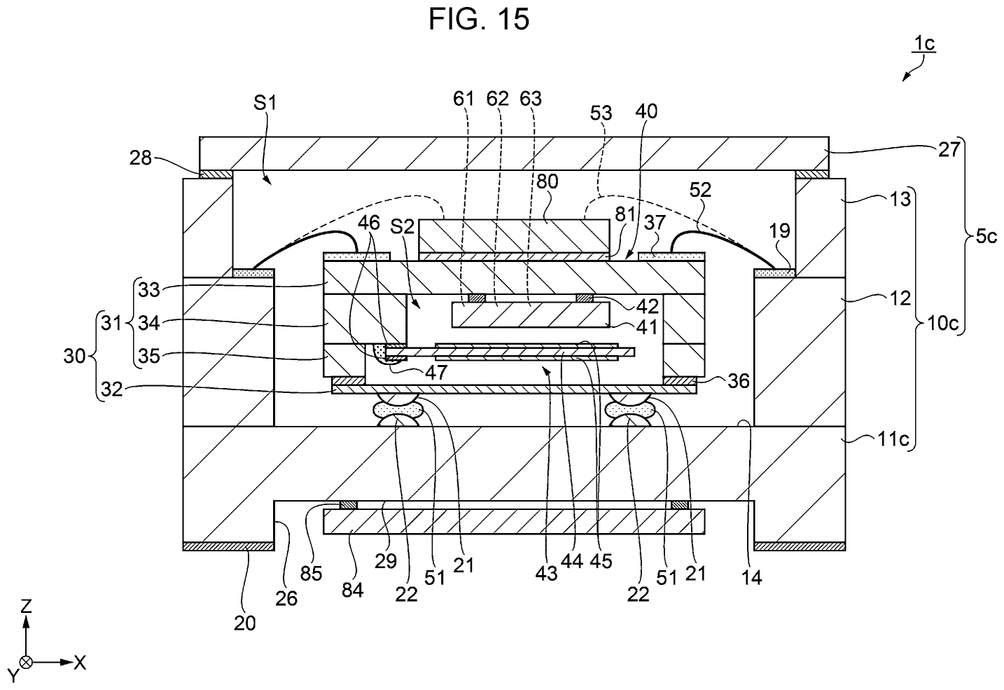

Next, an oscillator 1c manufactured by a method of manufacturing an oscillator according to a fourth embodiment will be described with reference to FIGS. 14 and 15. For convenience of description, FIG. 14 illustrates a state in which the lid 27 is removed.

The oscillator 1c of the present embodiment is the same as the oscillator 1 of the first embodiment except that the structure of a base substrate 10c is different compared to the oscillator 1 of the first embodiment and a heater 80 and a heater control integrated circuit 84 are disposed. Differences from the first embodiment described above will be mainly described, and the description of the same matters will be omitted.

In the oscillator 1c, as illustrated in FIGS. 14 and 15, the heater 80 is fixed to a surface of the container 30 of the temperature compensated oscillator 40, on which the terminals 37 are disposed, with a bonding member 81 such as a conductive adhesive having a high heat transfer rate interposed therebetween. Terminals 82 provided in the heater 80 and internal terminals 24 provided on the second substrate 12 of the base substrate 10c are electrically connected via bonding wires 53.

In a first substrate 11c of an accommodation container 5c, a recessed portion 26 recessed to the first surface 14 side is formed on the second surface 15. The heater control integrated circuit 84 for controlling the heater 80 is fixed to an inner bottom surface 29 of the recessed portion 26 with conductive bonding members 85 such as metal bumps or solder interposed therebetween. In addition, the heater control integrated circuit 84 is electrically connected to the internal terminals 24 provided on the base substrate 10c via wiring (not illustrated), through electrodes (not illustrated), or the like provided on the inner bottom surface 29 of the recessed portion 26. Therefore, by controlling the heater 80 to a constant temperature by the heater control integrated circuit 84, the temperature compensated oscillator 40 can be maintained at a constant temperature, and the frequency stability of the output oscillation frequency can be further improved.

A method of manufacturing the oscillator 1c of the present embodiment includes, in the sealing step S4, mounting the heater 80 and the heater control integrated circuit 84 and bonding the terminals 82 provided in the heater 80 and the internal terminals 24 provided on the second substrate 12 of the base substrate 10c. As a result, it is possible to manufacture the oscillator 1c having highly stable frequency characteristics.

### 5. First Modification

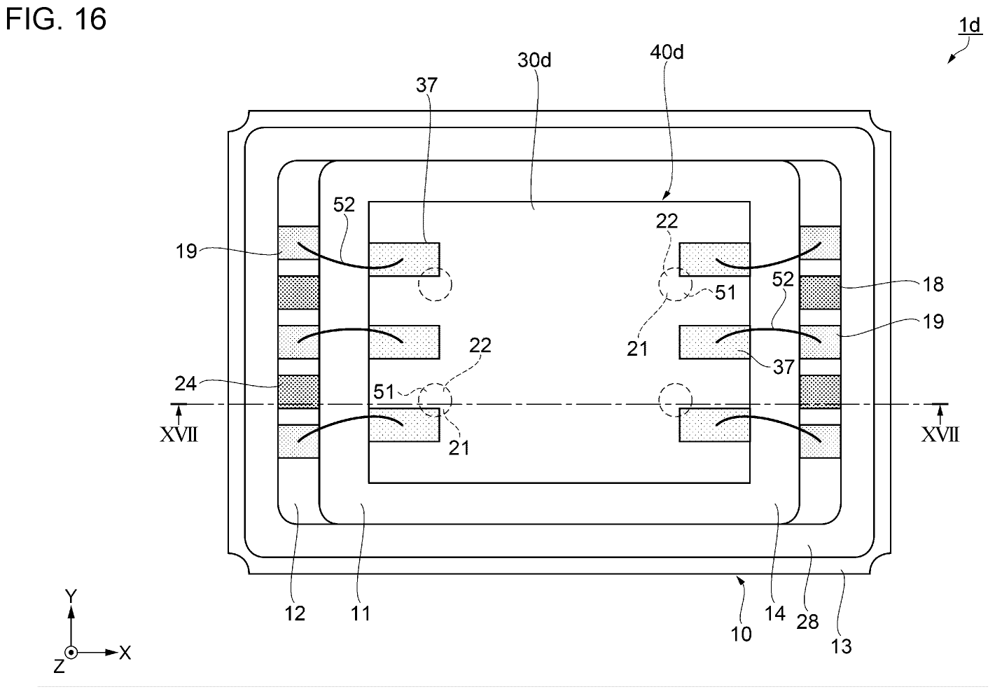

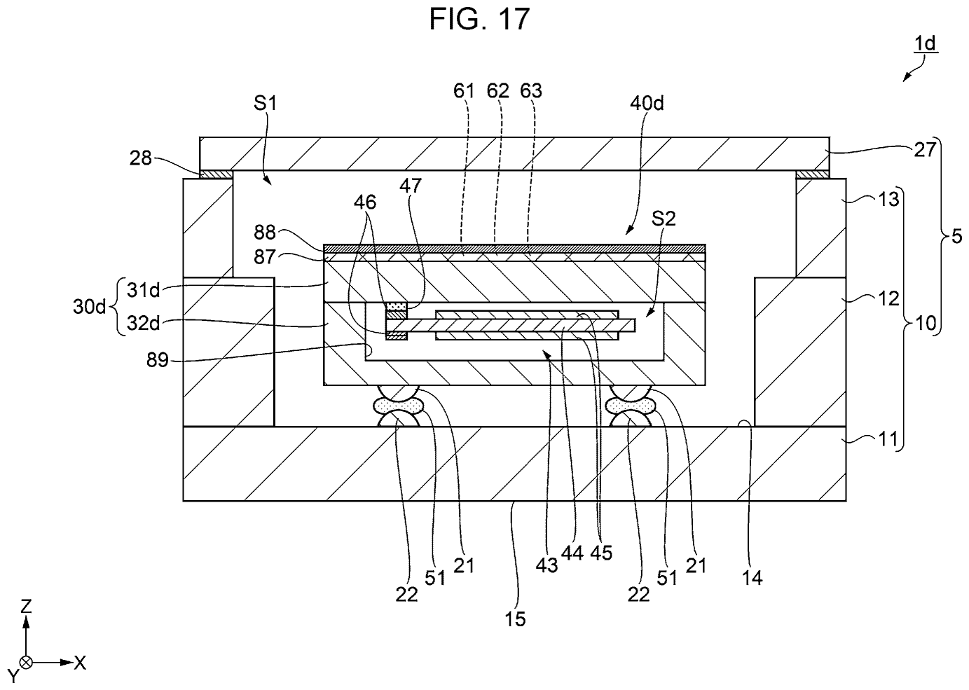

Next, an oscillator 1d according to a first modification will be described with reference to FIGS. 16 and 17. For convenience of description, FIG. 16 illustrates a state in which the lid 27 is removed.

The oscillator 1d of the present embodiment is the same as the oscillator 1 of the first embodiment except that the structure of a temperature compensated oscillator 40d is different compared to the oscillator 1 of the first embodiment. Differences from the first embodiment described above will be mainly described, and the description of the same matters will be omitted.

As illustrated in FIGS. 16 and 17, the oscillator 1d includes the temperature compensated oscillator 40d that includes an integrated circuit 87 and in which the resonator 43 is accommodated in a container 30d, and the accommodation container 5 that accommodates the temperature compensated oscillator 40d.

The temperature compensated oscillator 40d includes the container 30d in which the integrated circuit 87 is formed and that accommodates the resonator 43.

The container 30d includes a base 31d formed of a semiconductor substrate using silicon as a main material and a lid 32d, and the base 31d and the lid 32d are directly bonded.

In the base 31d, the integrated circuit 87 is formed on a surface opposite to the lid 32d, and a passivation film 88 for protecting the integrated circuit 87 is provided on a surface of the integrated circuit 87. The oscillation circuit 61, the temperature compensation circuit 62, and the temperature sensor 63 are formed in the integrated circuit 87. In addition, the resonator 43 is fixed to a surface of the base 31d on the lid 32d side with the bonding member 47 such as a gold bump interposed therebetween.

The lid 32d is provided with a recessed portion 89 recessed to a side opposite to the base 31d and is bonded to the base 31d, thereby forming the accommodation space S2 that accommodates the resonator 43. The first projecting portions 21 are provided on a surface of the lid 32d on a side opposite to the base 31d, and the container 30d is mounted on the base substrate 10 by bonding each first projecting portion 21 and each second projecting portion 22 provided on the base substrate 10 with the bonding material 51 interposed therebetween.

In the oscillator 1d of the present modification, the first projecting portions 21 are formed on the container 30d accommodating the resonator 43, the second projecting portions 22 are formed on the base substrate 10, and then each first projecting portion 21 and each second projecting portion 22 are bonded to each other with the bonding material 51 interposed therebetween, whereby the container 30d accommodating the resonator 43 is mounted on the base substrate 10. Therefore, it is possible to increase the gap between the container 30d and the base substrate 10, and it is possible to obtain the oscillator 1d having improved heat insulation properties and excellent frequency stability.

### 6. Second Modification

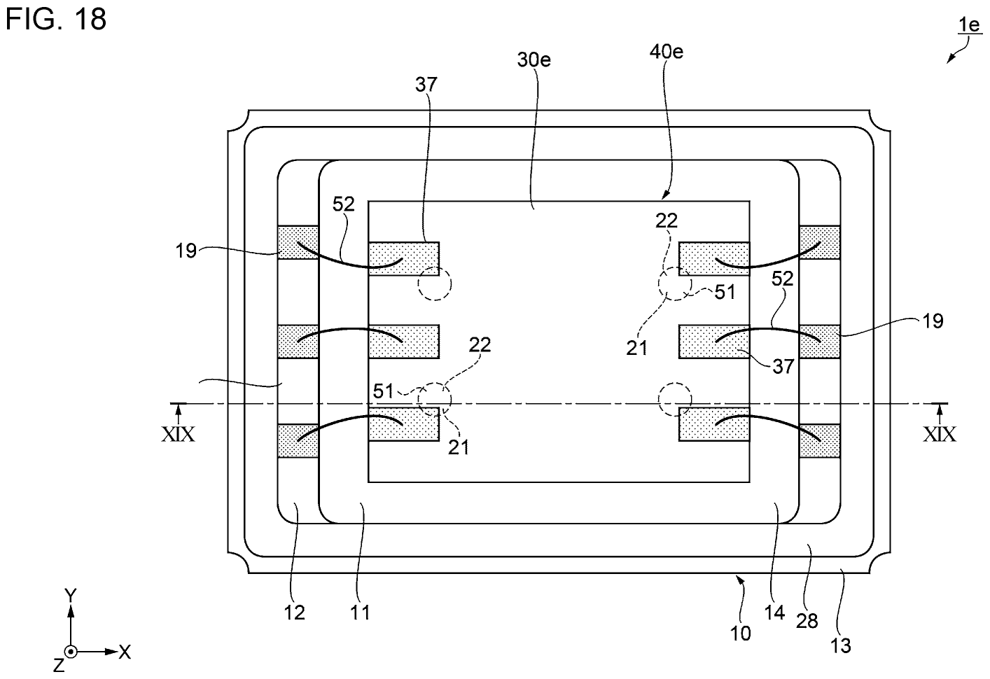

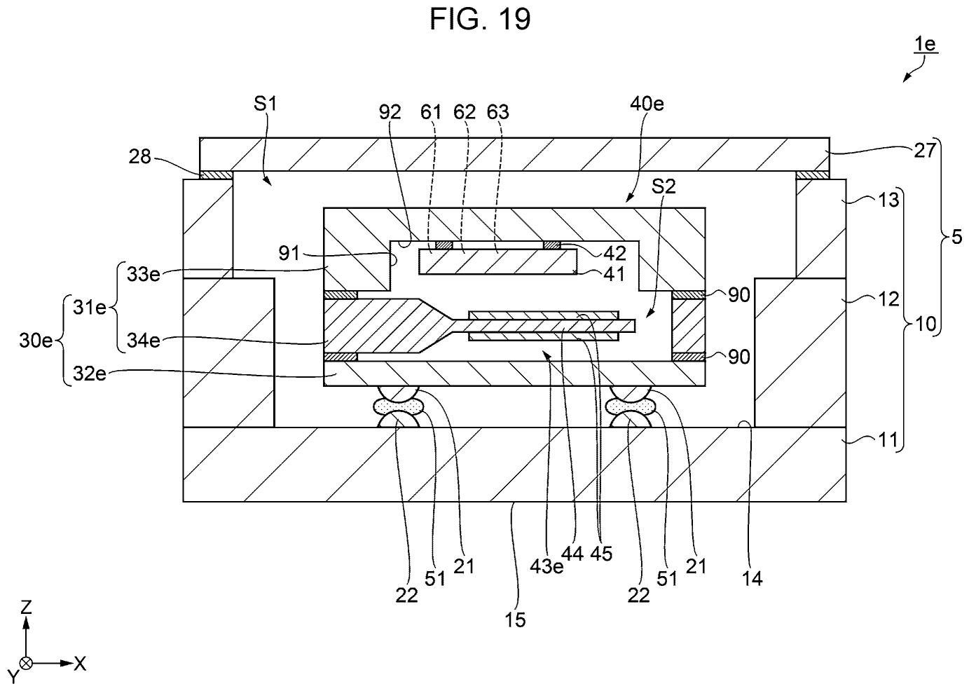

Next, an oscillator 1e according to a second modification will be described with reference to FIGS. 18 and 19. For convenience of description, FIG. 18 illustrates a state in which the lid 27 is removed.

The oscillator 1e of the present embodiment is the same as the oscillator 1 of the first embodiment except that the structure of a temperature compensated oscillator 40e is different compared to the oscillator 1 of the first embodiment. Differences from the first embodiment described above will be mainly described, and the description of the same matters will be omitted.

As illustrated in FIGS. 18 and 19, the oscillator 1e includes the temperature compensated oscillator 40e in which a resonator 43e and the integrated circuit 41 are accommodated in a container 30e, and the accommodation container 5 that accommodates the temperature compensated oscillator 40e.

The temperature compensated oscillator 40e includes the integrated circuit 41, the resonator 43e, and the container 30e that accommodates the resonator 43e and the integrated circuit 41.

The container 30e includes a base 31e and a lid 32e formed of quartz crystal substrates, and the base 31e and the lid 32e are bonded to each other with a bonding member 90 interposed therebetween.

The base 31e includes a first substrate 33e having a recessed portion 91 recessed to a side opposite to the lid 32e, and a second substrate 34e connected to an end portion of the resonator 43e on the minus side in the X direction and having a frame portion surrounding the resonator 43e. The first substrate 33e and the second substrate 34e are bonded with the bonding member 90 interposed therebetween. The integrated circuit 41 is fixed to an inner bottom surface 92 of the recessed portion 91 of the first substrate 33e with the bonding members 42 interposed therebetween. The resonator 43e of the present embodiment has an inverted mesa structure in which the plate thickness of the resonator 43e is thinner than the plate thickness of the frame portion of the second substrate 34e.

The first substrate 33e and the second substrate 34e constituting the base 31e of the present embodiment, and the lid 32e are AT cut quartz crystal substrates. Therefore, it is possible to reduce the influence of distortion caused by a difference in linear expansion coefficient due to bonding, and to obtain the resonator 43e having excellent temperature characteristics. In addition, the first substrate 33e and the lid 32e are not limited to a quartz crystal substrate, and may be a glass material such as soda lime glass or silica glass.

The first projecting portions 21 are provided on a surface of the lid 32e on a side opposite to the base 31e, and the container 30e is mounted on the base substrate 10 by bonding each first projecting portion 21 and each second projecting portion 22 provided on the base substrate 10 with the bonding material 51 interposed therebetween.

In the oscillator 1e of the present modification, the first projecting portions 21 are formed on the container 30e accommodating the resonator 43e, the second projecting portions 22 are formed on the base substrate 10, and then each first projecting portion 21 and each second projecting portion 22 are bonded to each other with the bonding material 51 interposed therebetween, whereby the container 30e accommodating the resonator 43e is mounted on the base substrate 10. Therefore, it is possible to increase the gap between the container 30e and the base substrate 10, and it is possible to obtain the oscillator 1e having improved heat insulation properties and excellent frequency stability.

What is claimed is:

1. A method of manufacturing an oscillator including a container in which a resonator is accommodated and a base substrate, the method comprising:
forming a first projecting portion on the container;
forming a second projecting portion on the base substrate; and
bonding the first projecting portion and the second projecting portion with a bonding material interposed therebetween to mount the container on the base substrate.

2. The method of manufacturing an oscillator according to claim 1, wherein
the first projecting portion is formed by applying an insulating adhesive to the container and curing the insulating adhesive, and
the second projecting portion is formed by applying an insulating adhesive to the base substrate and curing the insulating adhesive.

3. The method of manufacturing an oscillator according to claim 1, wherein
the container includes a base and a lid, and
the first projecting portion is formed on the lid.

4. The method of manufacturing an oscillator according to claim 3, wherein
the container includes a terminal formed on the base, and
the terminal and the base substrate are electrically connected to each other via a bonding wire.

5. The method of manufacturing an oscillator according to claim 1, wherein
the second projecting portion includes a plurality of projections, and
the first projecting portion includes a projection having a larger area in a plan view than any of the plurality of projections of the second projecting portion.

6. The method of manufacturing an oscillator according to claim 5, wherein
the projection of the first projecting portion is bonded to each of the plurality of projections of the second projecting portion.

7. The method of manufacturing an oscillator according to claim 5, wherein
the projection of the first projecting portion is bonded to any one of the plurality of projections of the second projecting portion.

8. The method of manufacturing an oscillator according to claim 1, wherein
the oscillator includes an integrated circuit including an oscillation circuit accommodated in the container.

9. The method of manufacturing an oscillator according to claim 8, wherein
the integrated circuit further includes a temperature compensation circuit and a temperature sensor.

10. The method of manufacturing an oscillator according to claim 9, wherein
the oscillator further includes a heater fixed to the container.
